(19) United States
(12) Patent Application Publication
(10) Pub. No.: US 2019/0371961 A1
(43) Pub. Date: Dec. 5, 2019

(54) SEMICONDUCTOR DEVICE AND METHOD OF MANUFACTURING THE SAME

(71) Applicant: XIAMEN SAN'AN OPTOELECTRONICS CO., LTD., Xiamen (CN)

(72) Inventors: CHANG-CHENG CHUO, XIAMEN (CN); SHENGCHANG CHEN, XIAMEN (CN); HEQING DENG, XIAMEN (CN)

(21) Appl. No.: 16/540,421

(22) Filed: Aug. 14, 2019

Related U.S. Application Data
(63) Continuation-in-part of application No. PCT/CN2018/078671, filed on Mar. 12, 2018.

(30) Foreign Application Priority Data
Jul. 20, 2017 (CN) 201710596729.3

(51) Int. Cl. H01L 33/00; H01L 33/04; H01L 33/12

(52) U.S. Cl. CPC H01L 33/007; H01L 33/12; H01L 33/04

(57) ABSTRACT

A semiconductor device includes a substrate, a stress tuning layer disposed on the substrate, an aluminum nitride (AlN) buffer layer disposed on the stress tuning layer, an n-type semiconductor layer disposed on the AlN buffer layer, an active layer disposed on the n-type semiconductor layer, and a p-type semiconductor layer disposed on the active layer. The stress tuning layer has a lattice constant larger than that of the AlN buffer layer and no larger than that of the n-type semiconductor layer. A method of manufacturing the semiconductor device is also provided.

### CROSS-REFERENCE TO RELATED APPLICATIONS

This application is a continuation-in-part (CIP) of International Application No. PCT/CN2018/078671, filed on Mar. 12, 2018, which claims priority to Chinese Invention Patent Application No. 201710596729.3, filed Jul. 20, 2017.

### FIELD

The disclosure relates to a semiconductor device, more particularly to a semiconductor device with a stress tuning layer and a method of manufacturing the same.

### BACKGROUND

In recent years, with improvements in technology and efficiency, ultraviolet light emitting diodes (UV LEDs), with their longer lifespan and smaller volume, have been slowly replacing mercury lamps of lower efficiency. With the Minamata Convention on Mercury coming into effect in 2020, the global ban on mercury would further expedite the rise of application of the UV LEDs.

FIG. 1 shows an epitaxial structure of the conventional deep UV LED. A conventional deep UV LED generally has an aluminum nitride (AlN)-based buffer layer 120 formed on a substrate 110. An n-type nitride semiconductor layer 130, a quantum well light emitting layer 140 and a p-type nitride semiconductor layer 150 are formed sequentially on the AlN-based buffer layer 120. In particular, because there is lattice mismatch between the n-type nitride semiconductor layer 130 and the AlN-based buffer layer 120, high compressive stress is experienced by the latter-grown aluminum gallium nitride (AlGaN) layers serving as the n-type nitride semiconductor layer 130, the quantum well light emitting layer 140 and the p-type nitride semiconductor layer 150, which causes an increase in the dislocation density and affects the lattice quality as well as the luminous efficiency of the conventional deep UV LED LED.

### SUMMARY

Therefore, an object of the disclosure is to provide a semiconductor device that can at least alleviate the drawbacks of the prior art. A method of manufacturing the semiconductor device is also provided.

According to one aspect of the disclosure, a semiconductor device includes a substrate, a stress tuning layer disposed on the substrate, an aluminum nitride (AlN) buffer layer disposed on the stress tuning layer, an n-type semiconductor layer disposed on the AlN buffer layer, an active layer disposed on the n-type semiconductor layer, and a p-type semiconductor layer disposed on the active layer.

The stress tuning layer has a lattice constant larger than that of the AlN buffer layer and no larger than that of the n-type semiconductor layer.

According to another aspect of the disclosure, a method of manufacturing a semiconductor device includes providing a growth substrate, and forming sequentially on the growth substrate a stress tuning layer, an AlN buffer layer, an n-type semiconductor layer, an active layer and a p-type semiconductor layer.

The stress tuning layer is adjusted to have a lattice constant larger than that of the AlN buffer layer and no larger than that of the n-type semiconductor layer.

### BRIEF DESCRIPTION OF THE DRAWINGS

Other features and advantages of the disclosure will become apparent in the following detailed description of the embodiments with reference to the accompanying drawings, of which:

FIG. 1 is a schematic view of an epitaxial structure of a conventional deep ultraviolet light emitting diode;

FIG. 2 is a schematic view of an embodiment of a semiconductor device according to the disclosure

FIGS. 3-5 are scanning electron microscope (SEM) images of surfaces of n-type semiconductor layers, which are applicable to the embodiment of the semiconductor device, formed respectively in the absence of or in the presence of a stress tuning layer with different compositions; and

FIG. 6 is a graph illustrating growth conditions of an embodiment of a method of manufacturing a semiconductor device according to the disclosure.

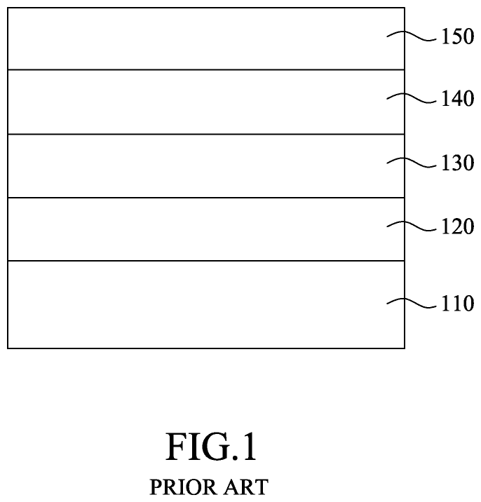

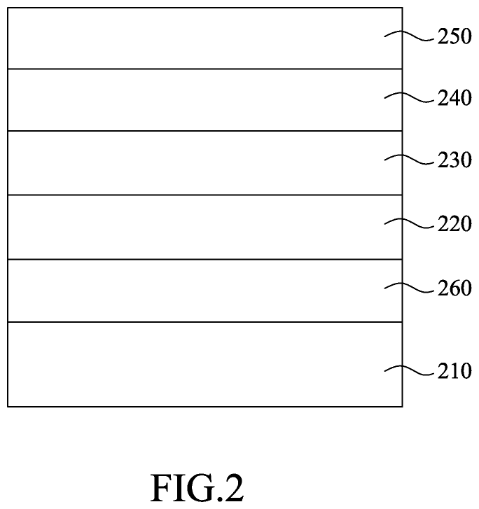

### DETAILED DESCRIPTION

Before the present invention is described in greater detail, it should be noted that where considered appropriate, reference numerals or terminal portions of reference numerals have been repeated among the figures to indicate corresponding or analogous elements, which may optionally have similar characteristics.

An embodiment of a semiconductor device according to the present disclosure includes a substrate 210, a stress tuning layer 260 disposed on the substrate 210, an aluminum nitride (AlN) buffer layer 220 disposed on the stress tuning layer 260, an n-type semiconductor layer 230 disposed on the AlN buffer layer 220, an active layer 240 disposed on the n-type semiconductor layer 230, and a p-type semiconductor layer 250 disposed on the active layer 240.

The substrate 210 may be a substrate for epitaxial growth. In this embodiment, the substrate 210 is a sapphire substrate.

The stress tuning layer 260 has a structural formula of AlₓGa₁₋ₓN, wherein x is between 0.2 and 0.9. The stress tuning layer 260 has a thickness that is no less than that of the AlN buffer layer 220. In this embodiment, the stress tuning layer 260 has a thickness (d1) ranging from 100 nm to 5000 nm, and the AlN buffer layer 220 has a thickness (d2) ranging from 10 nm to 3000 nm.

The n-type semiconductor layer 230 is an n-type aluminum gallium nitride (AlGaN) layer that has a structural formula of AlGa_{1-y}N, wherein y is between 0.5 and 1 and that may be silane-doped.

The active layer 240 has a multiple-quantum-well structure having a structural formula of Alₓ₁Ga₁₋ₓ₁N/Alₓ₂Ga₁₋ₓ₂N, wherein x1 is less than x2. In this embodiment, x1 is between 0.3 and 0.9 (for example 0.4), and x2 is between 0.6 and 1 (for example 0.6).

The stress tuning layer 260 has a lattice constant larger than that of the AlN buffer layer 220 and no larger than that of the n-type semiconductor layer 230. In this embodiment, the lattice constant of the stress tuning layer 260 ranges from 3.119 \acute{Å} to 3.174 \acute{Å}, the lattice constant of the AlN buffer layer 220 is 3.112 \acute{Å}, and the lattice constant of the n-type semiconductor layer 230 ranges from 3.112 \acute{Å} to 3.151 \acute{Å}. In particular, the lattice constant of the stress tuning layer 260 is 3.119 \acute{Å} when the structural formula is Al_{0.9}Ga_{0.1}N and 3.174 \acute{Å} when the structural formula is Al_{0.2}Ga_{0.8}N.

The p-type semiconductor layer 250 includes at least one doped AlGaN layer and a doped gallium nitride (GaN) layer. In this embodiment, the p-type semiconductor layer 250 includes a first magnesium (Mg)-doped p-type AlGaN layer serving as a barrier layer, a second Mg-doped p-type AlGaN layer, and an Mg-doped p-type gallium nitride (GaN) layer formed in this order.

In an embodiment of a method of manufacturing the embodiment of the semiconductor device according to the present disclosure, metal organic chemical vapor deposition technique (MOCVD) is used to epitaxially grow layers on the substrate 210 made of sapphire. Trimethylgallium (TMGa) and triethylgallium (TEGa), trimethylindium (TMIn), trimethylaluminum (TMAl), ammonia gas (NH₃), silane (SiH₄), and bis(cyclopentadienyl) magnesium (Cp2Mg) are used to respective provide a gallium source, an indium source, an aluminum source, a nitrogen source, a silicon source and a magnesium source. The method includes the steps:

(1) Cleaning the sapphire substrate 210 and then placing the sapphire substrate 210 into MOCVD equipment and being baked at 1100° C. for 10 minutes.

(2) At a growth temperature of between 1000° C. to 1300° C., forming the stress tuning layer 260 on the sapphire substrate 210 to have a thickness of between 100 nm to 1000 nm. The lattice constant of the stress tuning layer 260 thus formed is adjusted to be larger than the lattice constant of the AlN buffer layer 220 and no larger than the lattice constant of the n-type semiconductor layer 230 by controlling a flux of the gallium source or a flux of the aluminum source. Then, in the structural formula of AlₓGa₁₋ₓN of the resulting stress tuning layer 260, x ranges between 0.2 and 0.9, and more particularly between 0.5 and 0.9.

(3) At a growth temperature of between 1200° C. and 1450° C., forming the AlN buffer layer 220 on the stress tuning layer 260. The thickness of the AlN buffer layer 220 thus formed falls within the abovementioned range of 10 nm to 3000 nm, and more particularly between 1000 nm and 3000 nm.

(4) Forming the n-type AlGaN layer 230 that is silane-doped on the AlN buffer layer 220.

(5) Forming the active layer 240 of the abovementioned multiple-quantum-well structure on the n-type semiconductor layer 230.

(6) Growing on the active layer 240 sequentially the barrier layer of the first Mg-doped p-type AlGaN layer, the second Mg-doped p-type AlGaN layer, and the Mg-doped p-type GaN layer to form the p-type semiconductor layer 250.

Specifically, when sequentially forming the stress tuning layer 260, the AlN buffer layer 220, the n-type semiconductor layer 230, the active layer 240 and the p-type semiconductor layer 250, a flux of the aluminum source (the flux of TMAl) is fixed while a flux of the gallium source (the flux of TMGa) is varied. For example, the x present in the structural formula of AlₓGa₁₋ₓN of the stress tuning layer 260, which is grown at an elevated temperature, is changeable based on adjustments of parameters for growing the n-type AlGaN layer 230. A value (f1) of the flux of the gallium source during formation of the n-type semiconductor layer 230 is greater than a value (f2) of the flux of the gallium source during formation of the stress tuning layer 260 of the structural formula of AlₓGa₁₋ₓN so as to control a value of the x. In certain embodiments, the value (f2) is half of the value (f1). Similarly, the flux of TMGa may be fixed while the flux of TMAl is varied.

In this embodiment, the x present in the structural formula of AlₓGa₁₋ₓN of the stress tuning layer 260 may also be adjustable by controlling growth temperatures of the stress tuning layer 260, the AlN buffer layer 220, and the n-type semiconductor layer 230. For example, the stress tuning layer 260 is formed at the growth temperature of T1, the AlN buffer layer 220 is formed at the growth temperature of T2, and the n-type semiconductor layer 230 is formed at the growth temperature of T3, where T1, T2 and T3 satisfy a relation of T3<T1<T2. In certain embodiments, T1, T2, and T3 satisfy a relation of T1=(T2+T3)/2.

In a variation of the embodiment of the method of manufacturing the semiconductor device according to the present disclosure, the MOVCD technique is used to perform epitaxial growth on the sapphire substrate 210. Trimethylgallium (TMGa) and triethylgallium (TEGa), trimethylindium (TMIn), trimethylaluminum (TMAl), ammonia gas (NH₃), silane (SiH₄), and bis(cyclopentadienyl)magnesium (Cp2Mg) are used to respective provide the gallium source, the indium source, the aluminum source, the nitrogen source, the silicon source and the magnesium source. The variation of the method includes the following steps:

(1) Cleaning the sapphire substrate 210, and then placing the sapphire substrate 210 into the MOCVD equipment and baking at 1100° C. for 10 minutes.

(2) At a growth temperature of between 1000° C. to 1300° C., forming the stress tuning layer 260 on the substrate 210 to have the thickness of between 1000 nm to 3000 nm. The x present in the structural formula of AlₓGa₁₋ₓN of the stress tuning layer 260 is between 0.2 and 0.9. In certain embodiments, x is between 0.6 and 0.9

(3) At a growth temperature of between 1200° C. and 1450° C., forming the AlN buffer layer 220 on the stress tuning layer 260 so as to have the thickness of 10 nm to 3000 nm. In certain embodiments, the thickness is between 500 nm and 1000 nm.

(4) Forming the n-type AlGaN layer 230 that is silane-doped, on the AlN buffer layer 220.

(5) Forming the active layer 240 of the abovementioned multiple-quantum-well structure on the n-type semiconductor layer 230.

(6) Growing on the active layer 240 sequentially the barrier layer of the first Mg-doped p-type AlGaN layer, the second Mg-doped p-type AlGaN layer, and the Mg-doped p-type GaN layer to form the p-type semiconductor layer 250.

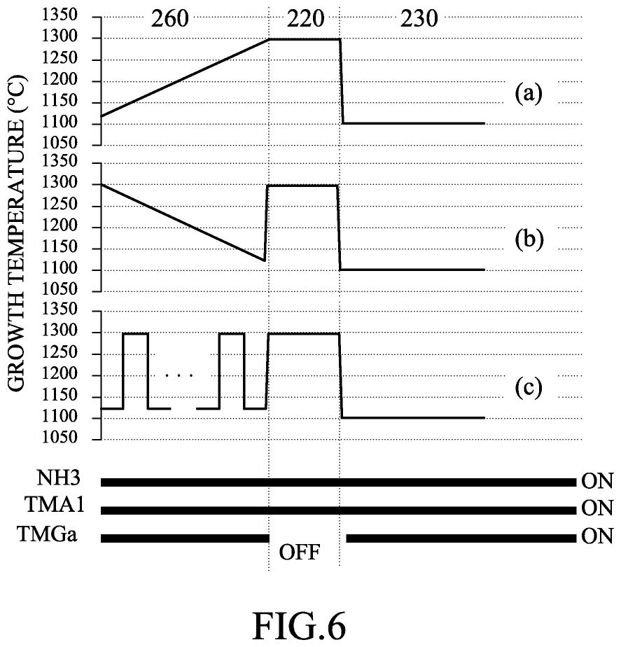

In this variation of the embodiment of the method, the x of the structural formula of AlₓGa₁₋ₓN of the stress tuning layer 260 maybe controlled by forming the stress tuning layer 260 under a gradually or periodically changing growth temperature. As shown in FIG. 6, the stress tuning layer 260 may be formed under a growth temperature curve in a gradual increase form, a gradual decrease form or a periodicity form.

In the following, influence of the stress tuning layer 260 on surface property of the n-type semiconductor layer 220 of the semiconductor device of the disclosure is evaluated. For evaluation, first and second Examples of semi-finished semiconductor devices of the disclosure and a Comparative Example were prepared. The semi-finished semiconductor devices of the first and second Examples were formed to only include the sapphire substrate 210, the stress tuning layer 260, the AlN buffer layer 220, and the n-type semiconductor layers 230, while the semi-finished semiconductor device of the Comparative Example was formed to only include the sapphire substrate 210, the AlN buffer layer 220, and the n-type semiconductor layers 230. The MOVCD technique was likewise used to perform the epitaxial growth on the sapphire substrate 210. Trimethylgallium (TMGa) and triethylgallium (TEGa), trimethylaluminum (TMAl), ammonia gas (NH₃), and silane (SiH₄) were used to respective act as the gallium source, the aluminum source, the nitrogen source, and the silicon source.

First, the sapphire substrates 210 for the first and second examples and comparative example were cleaned and then placed the into the MOCVD equipment and baked at 1100° C. for 10 minutes.

At a growth temperature of 1000° C. to 1300° C., the stress tuning layers 260 were respectively formed on the sapphire substrates 210 of the first and second examples to the thickness of between 1000 nm and 5000 nm, preferably between 2000 nm and 3000 nm. The x present in the structural formula of the stress tuning layer 260 is between 0.7 and 0.9.

At a growth temperature of between 1200° C. to 1450° C., the AlN buffer layers 220 were respectively formed on the stress tuning layers 260 of the first and second Examples and the sapphire substrate 210 of the Comparative Example without the stress tuning layer 260. The buffer layers 220 each have the thickness of 10 nm to 1500 nm, the thickness preferably being between 10 nm and 1000 nm, more preferably between 100 nm and 1000 nm.

The silane-doped n-type AlGaN layers 230 were respectively formed on the AlN buffer layers 220 of the first and second Examples and the Comparative Example to the thickness of between 1500 nm and 2500 nm. As mentioned above, the y present in the structural formula of AlGa_{1-y}N for the n-type AlGaN layer 230 was 0.55.

Specifically, the stress tuning layers 260 in the first and second Examples were formed with the x to be 0.9 and more optimally 0.8, respectively.

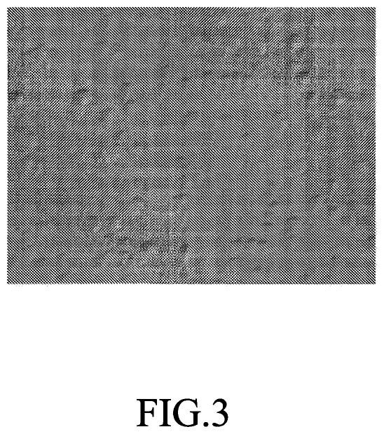

Surface properties of the n-type semiconductor layer 230 of the Comparative Example and the n-type semiconductor layers 230 of the Examples are respectively illustrated by scanning electron microscope (SEM) images shown in FIGS. 3 to 5.

As shown in FIG. 3, for the Comparative Example, the surface of the n-type AlGaN layer 230 without the stress tuning layer 260 has a high density of pyramidal bumps resulting from lattice mismatch with the AlN buffer layer 220.

As shown in FIG. 4, for the first Example, the growth of the pyramidal bumps is suppressed on the surface of the n-type AlGaN layer 230, as stress on the surface was lowered due to the stress tuning layer 260 with the x of 0.9.

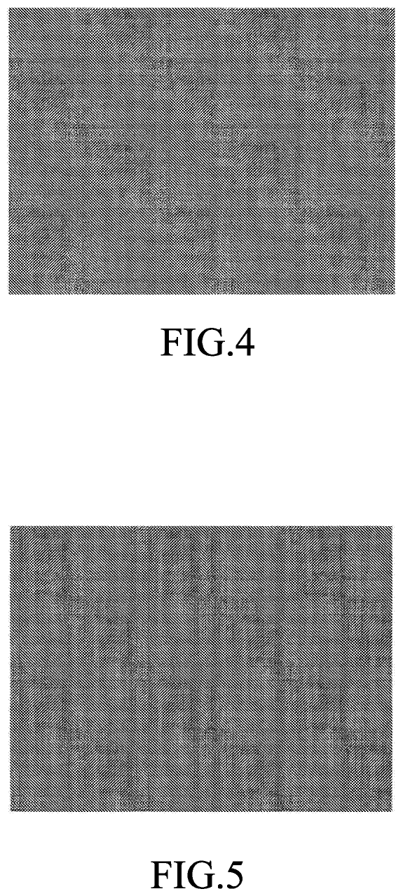

As shown in FIG. 5, for the second Example, the surface of the n-type semiconductor layer 230 with the more optimized stress tuning layer 260 with the x of 0.8 achieved a more optimized smoothness. Furthermore, for the second Example, an in-situ curvature of the active layer 240 formed on the n-type AlGaN layer 230 may be reduced from a range of 100 km-⁻¹ to 300 km⁻¹ to a range of 0 km-⁻¹ to 200 km⁻¹ or even a range of 0 km-⁻¹ to 100 km⁻¹, improving the uniformity and crystal quality of the active layer 240.

In the description above, for the purposes of explanation, numerous specific details have been set forth in order to provide a thorough understanding of the embodiments. It will be apparent, however, to one skilled in the art, that one or more other embodiments maybe practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A semiconductor device comprising:
a substrate;
a stress tuning layer disposed on said substrate;
an aluminum nitride (AlN) buffer layer disposed on said stress tuning layer;
an n-type semiconductor layer disposed on said AlN buffer layer;
an active layer disposed on said n-type semiconductor layer; and
a p-type semiconductor layer disposed on said active layer,
wherein said stress tuning layer has a lattice constant larger than that of said AlN buffer layer and no larger than that of said n-type semiconductor layer.

2. The semiconductor device as claimed in claim 1, wherein said lattice constant of said stress tuning layer ranges from 3.119 \acute{Å} to 3.174 \acute{Å}.

3. The semiconductor device as claimed in claim 2, wherein said lattice constant of said n-type semiconductor layer ranges from 3.112 \acute{Å} to 3.151 \acute{Å}.

4. The semiconductor device as claimed in claim 1, wherein said stress tuning layer has a structural formula of AlₓGa₁₋ₓN, wherein x is between 0.2 and 0.9.

5. The semiconductor device as claimed in claim 1, wherein said stress tuning layer has a thickness that is no less than that of said AlN buffer layer.

6. The semiconductor device as claimed in claim 1, wherein said stress tuning layer has a thickness ranging from 100 nm to 5000 nm.

7. The semiconductor device as claimed in claim 1, wherein said AlN buffer layer has a thickness ranging from 10 nm to 3000 nm.

8. The semiconductor device as claimed in claim 1, wherein said active layer has a convex curvature ranging from 0 km⁻¹ to 200 km⁻¹.

9. The semiconductor device as claimed in claim 1, wherein said n-type semiconductor layer is an n-type aluminum gallium nitride (AlGaN) layer, said active layer having a multiple-quantum-well structure, said p-type semiconductor layer including at least one doped p-type AlGaN layer and a doped p-type gallium nitride (GaN) layer.

10. A method of manufacturing a semiconductor device comprising;
providing a growth substrate; and
forming sequentially on the growth substrate a stress tuning layer, an AlN buffer layer, an n-type semiconductor layer, an active layer and a p-type semiconductor layer,
wherein the stress tuning layer is adjusted to have a lattice constant larger than that of the AlN buffer layer and no larger than that of the n-type semiconductor layer.

11. The method as claimed in claim 10, wherein the stress tuning layer, the AlN buffer layer, the n-type semiconductor layer, the active layer and the p-type semiconductor layer are formed using chemical vapor deposition technique.

12. The method as claimed in claim 11, wherein the stress tuning layer is formed at a growth temperature ranging from 1000° C. to 1300° C.

13. The method as claimed in claim 10, wherein the stress tuning layer has a structural formula of AlₓGa₁₋ₓN, x being between 0.2 and 0.9.

14. The method as claimed in claim 10, wherein the stress tuning layer has a thickness no less than that of the AlN buffer layer.

15. The method as claimed in claim 10, wherein the stress tuning layer is formed to have a lattice constant which is larger than a lattice constant of the AlN buffer layer and no larger than a lattice constant of the n-type semiconductor layer by controlling a flux of one of a gallium source and an aluminum source.

16. The method as claimed in claim 15, wherein the lattice constant of the stress tuning layer has a range of 3.119 \acute{Å} to 3.174 \acute{Å}.

17. The method as claimed in claim 10, wherein when sequentially forming the stress tuning layer, the AlN buffer layer, the n-type semiconductor layer, the active layer and the p-type semiconductor layer, a flux of an aluminum source is fixed while a flux of a gallium source is varied, and wherein a value of the flux of the gallium source during formation of the n-type semiconductor layer is greater than a value of the flux of the gallium source during formation of the stress tuning layer.

18. The method as claimed in claim 10, wherein the stress tuning layer is formed at a growth temperature of T1, the AlN buffer layer is formed at a growth temperature of T2, and the n-type semiconductor layer is formed at a growth temperature of T3, where T1, T2 and T3 satisfy a relation of T3<T1<T2.

19. The method as claimed in claim 10, wherein the stress tuning layer is formed under a gradually changing growth temperature.

20. The method as claimed in claim 10, wherein the stress tuning layer is formed under a growth temperature curve in one of a gradual increase form, a gradual decrease form and a periodicity form.
